(19) United States
(12) Patent Application Publication
(10) Pub. No.: US 2006/0215361 A1
(43) Pub. Date: Sep. 28, 2006

(54) Housing of electronic product

(75) Inventors: Yung-Chi Yang, Taipei (TW); Yan Xiong, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/262,529

(22) Filed: Oct. 27, 2005

(30) Foreign Application Priority Data
Mar. 23, 2005 (TW) 94204481

(51) Int. Cl. H05K 7/20

(52) U.S. Cl. 361/687

(57) ABSTRACT

A housing of electronic product includes an accommodating space and at least one heat dissipating opening, wherein the heat dissipating opening is formed on an upper surface of the housing so as to allow a heat dissipating device received in the accommodating space to dissipate heat generated by operation of electronic components received in the accommodating space to improve heat dissipating efficiency.

### FIELD OF THE INVENTION

The present invention relates to electronic products, and more particularly, to a housing of electronic product.

### BACKGROUND OF THE INVENTION

With the development of information technology, common electronic products in the market, such as computer, electronic dictionary, personal digital assistant (PDA) and electronic game console, are widely used in daily life, wherein notebook computers may replace desktop computers having a large size so as to save occupied space on a desk, and the notebook computers are portable and occupy small space, making such light-weight and small-size notebook computers become popular. Heat dissipation is always a critical technical problem to electronic products. As high frequency devices of the electronic products generate a lot of heat during operation, in case the heat dissipating efficiency is not good, the operating quality and reliability of the electronic products are adversely affected. It is thus necessary to allow heat dissipating devices to effectively dissipate heat such that the electronic products can operate under a normal temperature range.

For example of a notebook computer, there are usually provided heat dissipating openings on a bottom surface of a housing of the notebook computer, such that a heat dissipating device received in an accommodating space of the housing can dissipate heat generated by operation of electronic components of the notebook computer. Generally, when using the notebook computer, a user places the housing of the notebook computer on his/her lap, a desktop or any of other supporting devices, and opens it to use when needed.

However, as the heat dissipating openings are provided on the bottom surface of the housing, great resistance is caused to operation of the heat dissipating device such as a fan received in the housing. As a result, an amount of air output from the heat dissipating device is decreased, and an air inlet/outlet path of the heat dissipating openings is impeded or even blocked by the above supporting device, thereby leading to unsatisfactory heat dissipating performance and inexplicable breakdowns due to unsatisfactory heating dissipation.

The situation of unsatisfactory heat dissipation also affects the performance and lifetime of a high frequency device such as central processing unit (CPU), video graphics adapter (VGA) or microprocessor in the electronic product. The provision of heat dissipating openings on the bottom surface of the housing causes great resistance to operation of the heat dissipating device received in the housing, which not only reduces the amount of air output from the heat dissipating device but also increases noise during operation of the heat dissipating device.

To solve the problems caused by unsatisfactory heat dissipating efficiency, for example, Taiwanese Utility Model Patent Nos. 450375 and 562162 both disclose a technology of performing heat dissipation by the bottom surface of the housing of electronic product.

Taiwanese Utility Model Patent No. 450375 proposes a structural improvement in a heat dissipating air inlet of a notebook computer, wherein the heat dissipating air inlet is formed on a bottom surface of a housing of the notebook computer and has a slanted structure. A slantwise air outlet is formed at a side adjacent the bottom surface of the housing and corresponds to the air inlet, so as to compulsively dissipate heat from the notebook computer to the outside via convection.

However, in the above conventional technology, a heat dissipating device of the notebook computer must also be arranged aslant in accordance with the slantwise air inlet, thereby increasing a thickness of the housing of the notebook computer and not favorable for the light-weight and small-size requirements of the notebook computer. Although the air inlet is slanted, an air inlet path thereof is still impeded by a supporting device or a front wall and causes a heat dissipating problem.

Taiwanese Utility Model Patent No. 562162 proposes an improved structure of a notebook computer, wherein an air outlet is formed at a lateral side of a housing of the notebook computer, a bottom ventilation opening is provided on a bottom surface of the housing and corresponds to a CPU in the notebook computer, and an air inlet is formed at a rear side of the housing. Although the air inlet and the air outlet are located at different sides of the housing, the bottom ventilation opening provided on the bottom surface of the housing still causes various problems as in the foregoing conventional technology. Further, the provision of air inlet at the rear side of the housing reduces the space for incorporating connection ports and slots, and thus affects functionality of the notebook computer.

Therefore, the problem to be solved here is to provide a housing of electronic product, which can overcome the drawbacks in the conventional technology such as unsatisfactory heat dissipating efficiency, great noise, increased thickness, and impaired quality and reliability of the electronic product.

### SUMMARY OF THE INVENTION

In light of the drawbacks in the foregoing conventional technology, an objective of the present invention is to provide a housing of electronic product, for effectively improving heat dissipating efficiency.

Another objective of the present invention is to provide a housing of electronic product, for reducing noise during operation of the electronic product.

Still another objective of the present invention is to provide a housing of electronic product, for improving quality and reliability of the electronic product without increasing a thickness thereof.

In accordance with the above and other objectives, the present invention proposes a housing of electronic product, comprising an accommodating space and at least one heat dissipating opening, wherein the heat dissipating opening is formed on an upper surface of the housing so as to allow a heat dissipating device received in the accommodating space to dissipate heat produced by operation of electronic components received in the accommodating space to improve heat dissipating efficiency.

Preferably, the housing is formed with at least two heat dissipating openings, wherein at least one of the heat dissipating openings is provided on the upper surface of the housing and serves as an air inlet.

In a preferred embodiment, the at least one heat dissipating opening is an air inlet. In another preferred embodiment, the at least one heat dissipating opening is an air outlet.

Preferably, the housing further comprises a speaker amplifier opening disposed symmetrically to the at least one heat dissipating opening, wherein the heat dissipating opening is an air inlet.

Since the heat dissipating opening is located on the upper surface of the housing, the heat dissipating device can effectively dissipate heat to ensure that the electronic product operates under a normal temperature range. Therefore, the present invention can solve problems of for example reduced air output from a heat dissipating device such as a fan received in a housing of electronic product and increased noise during operation of the heat dissipating device due to great resistance caused to the operation of the heat dissipating device as in the conventional technology.

As an air inlet/outlet path of the heat dissipating opening of the housing of electronic product in the present invention is not impeded or blocked by other devices or walls, a thickness of the housing is not necessarily increased, and an adverse effect on functionality of the electronic product as in conventional technology is avoided.

Consequently, the present invention can solve problems such as unsatisfactory heat dissipating efficiency, great noise, increased thickness, and impaired quality and reliability of the electronic product as in the conventional technology, so as to effectively improve heat dissipating efficiency and reduce noise during operation of the electronic product, such that quality and reliability of the electronic product are improved without increasing a thickness thereof.

### BRIEF DESCRIPTION OF THE DRAWINGS

The present invention can be more fully understood by reading the following, detailed description of the preferred embodiments, with reference made to the accompanying drawings, wherein:

FIG. 1 is a schematic diagram of a housing of electronic product according to a first preferred embodiment of the present invention; and

FIG. 2 is a schematic diagram of the housing of electronic product according to a second preferred embodiment of the present invention.

### DETAILED DESCRIPTION OF THE PREFERRED EMBODIMENTS

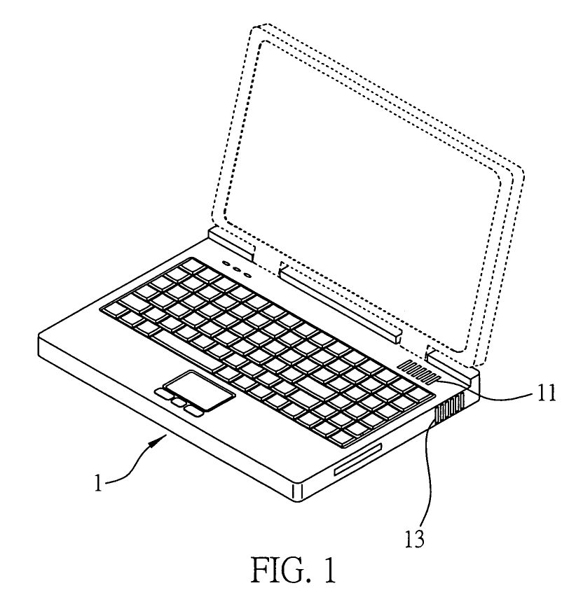

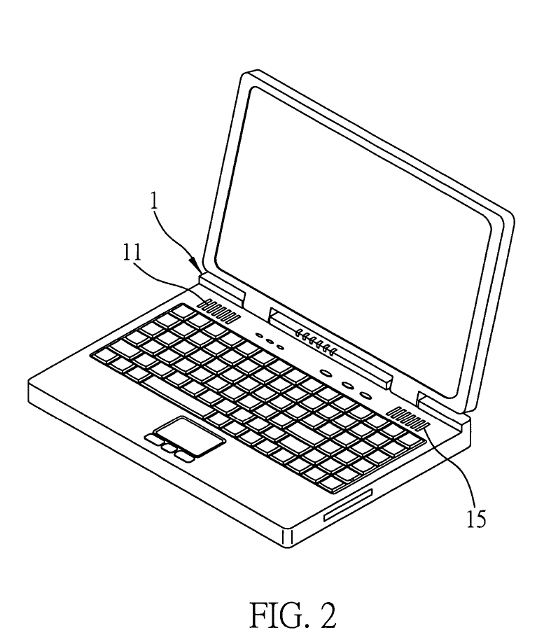

The preferred embodiments of a housing of electronic product proposed in the present invention are described as follows with reference to FIGS. 1 and 2, wherein the housing for a notebook computer is exemplified, and the structure and operation theory of the notebook computer are known in the art and thus not to be further detailed hereinafter. It should be understood that the housing of electronic product in the present invention is also applicable to other common electronic products in the market, such as computer, electronic dictionary, personal digital assistant (PDA) and electronic game console. The following drawings showing the structure of the housing are only for the purpose of illustration but not for limiting the present invention.

### FIRST PREFERRED EMBODIMENT

FIG. 1 is a schematic diagram of the housing of electronic product according to a first preferred embodiment of the present invention.

As shown in FIG. 1, the housing of electronic product 1 in this embodiment comprises an accommodating space (not shown), a first heat dissipating opening 11, and a second heat dissipating opening 13.

The accommodating space is used to receive essential components such as heat dissipating component, power source, floppy disk drive, mainboard, compact disc drive and others (all not shown) of the notebook computer therein, which are arranged or electrically connected to each other via buses or adapter circuit boards. Conventional components and devices used in the notebook computer are also applicable to this embodiment, those of which independent of the features of the present invention are not modified, such that for the sake of simplicity to make the features and structure of the present invention clear and understandable, only structures relating to the features of the housing in the present invention are shown in the drawings, and the others are omitted. As to components connected to the housing 1 such as keyboard, touch panel and display light, they are also conventional and not to be further detailed herein.

The first heat dissipating opening 11 is formed on an upper surface of the housing 1, and the second heat dissipating opening 13 is formed at a lateral side adjacent to the upper surface of the housing 1; from a view facing FIG. 1, the second heat dissipating opening 13 is located at a right side of the housing 1. In this embodiment, the first heat dissipating opening 11 can be an air inlet, and the second heat dissipating opening 13 can be an air outlet. The first heat dissipating opening 11 provides a large amount of non-blocked air input to a heat dissipating device such as a fan (not shown), allowing heat generated by operation of electronic components in the accommodating space to be dissipated via the second heat dissipating opening 13.

Since the first heat dissipating opening 11 is formed on the upper surface of the housing 1 in the present invention, a situation of unsatisfactory heat dissipating performance caused by impedance or blocking of an air inlet path of a heat dissipating opening as in the conventional technology is prevented, thereby effectively improving heat dissipating efficiency in the present invention. The housing 1 in the present invention may be used to minimize resistance to operation of the heat dissipating device and thus reduce noise thereof, such that the problems in conventional technology can be effectively solved. The housing 1 in the present invention also effectively improves the heat dissipating efficiency under a condition of satisfying the light-weight and small-size requirements of the notebook computer, and thus improves quality and reliability of the electronic product without increasing a thickness thereof.

### SECOND PREFERRED EMBODIMENT

FIG. 2 is a schematic diagram of the housing of electronic product according to a second preferred embodiment of the present invention, wherein same or similar elements as or to those in the first embodiment are designated with same or similar reference numerals and detailed descriptions thereof are omitted for the sake of clarify.

As shown in FIG. 2, the second embodiment primarily differs from the first embodiment in that, the first heat dissipating opening 11 is disposed symmetrically to a speaker amplifier opening 15.

In this embodiment, from a view facing FIG. 2, the first heat dissipating opening 11 is located at a left part of the upper surface of the housing 1 and can be an air inlet. The second heat dissipating opening 13 is located at a lateral side (such as a left side of the housing 1) adjacent to the upper surface of the housing 1 and can be an air outlet; the second heat dissipating opening 13 is not shown in FIG. 2 due to the angle reason. The speaker amplifier opening 15 is disposed at a right part of the upper surface of the housing 1 and is symmetrical to the first heat dissipating opening 11. Similarly, the first heat dissipating opening 11 can provide a large amount of non-blocked air input to the heat dissipating device such as a fan (not shown), allowing heat generated by operation of the electronic components in the accommodating space to be dissipated via the second heat dissipating opening 13. The first heat dissipating opening 11 and the speaker amplifier opening 15 may both be shaped as opening structures so as to improve quality and reliability of the electronic product and also provide design flexibility and value of the housing 1.

It should be noted that, although the first heat dissipating opening 11 serves as an air inlet in the first and second embodiments, those skilled in the art would understand that the first heat dissipating opening 11 may alternatively be used as an air outlet in the present invention; and the housing may alternatively be formed with at lease two heat dissipating openings serving as air inlets, wherein at least one of the heat dissipating openings is located on the upper surface of the housing so as to prevent an air inlet/outlet path of the heat dissipating openings from being impeded or blocked, but not limited to the arrangements in the above embodiments.

Similarly, the structures in the first and second embodiments may also be modified. For example, the first heat dissipating opening 11 of the first embodiment is formed at the left part of the upper surface of the housing 1; or, the speaker amplifier opening 15 of the second embodiment is formed at the left part of the upper surface of the housing 1, and the first heat dissipating opening 11 of the second embodiment is formed at a right part of the upper surface of the housing 1.

The invention has been described using exemplary preferred embodiments. However, it is to be understood that the scope of the invention is not limited to the disclosed embodiments. On the contrary, it is intended to cover various modifications and similar arrangement. The scope of the claims therefore should be accorded the broadest interpretation so as to encompass all such modifications and similar arrangements.

What is claimed is:

1. A housing of electronic product, comprising an accommodating space and at least one heat dissipating opening, wherein the heat dissipating opening is formed on an upper surface of the housing so as to allow a heat dissipating device received in the accommodating space to dissipate heat produced by operation of electronic components received in the accommodating space to improve heat dissipating efficiency.

2. The housing of electronic product as claimed in claim 1, wherein the housing comprises at least two heat dissipating openings.

3. The housing of electronic product as claimed in claim 2, wherein at least one of the heat dissipating openings is formed on the upper surface of the housing.

4. The housing of electronic product as claimed in claim 3, wherein the heat dissipating opening formed on the upper surface of the housing is an air inlet.

5. The housing of electronic product as claimed in claim 1, wherein the heat dissipating opening is an air inlet.

6. The housing of electronic product as claimed in claim 1, wherein the heat dissipating opening is an air outlet.

7. The housing of electronic product as claimed in claim 1, further comprising a speaker amplifier opening disposed symmetrically to the heat dissipating opening.

8. The housing of electronic product as claimed in claim 7, wherein the heat dissipating opening is an air inlet.
